(19) United States
(12) Patent Application Publication
(10) Pub. No.: US 2014/0340081 A1
(43) Pub. Date: Nov. 20, 2014

(54) MAGNETIC SENSOR

(71) Applicant: Norihiro Kurumado, Nagoya-city (JP)

(72) Inventor: Norihiro Kurumado, Nagoya-city (JP)

(73) Assignee: DENSO CORPORATION, Kariya-city, Aichi-pref. (JP)

(21) Appl. No.: 14/344,074

(22) PCT Filed: Aug. 28, 2012
(86) PCT No.: PCT/JP2012/005385

§ 371 Date: Mar. 11, 2014

(30) Foreign Application Priority Data
Oct. 17, 2011 (JP) 2011-227854

(51) Int. Cl. G01R 33/09

(52) U.S. Cl. CPC G01R 33/093
USPC 324/252

(57) ABSTRACT

A magnetic sensor includes a detection portion that includes first and second magnetic resistance elements. Each of the first and second magnetic resistance elements includes a pinned layer whose magnetic direction is fixed in a predetermined direction and a free layer whose magnetic direction changes in accordance with an external magnetic field. A resistance value of each of the first and second magnetic resistance elements changes in accordance with an angle between the magnetization direction of the pinned layer and the magnetization direction of the free layer. The first and second magnetic resistance elements are connected in series in a state where the magnetization directions of the pinned layers are perpendicular to each other. The detection portion outputs a middle point voltage of the first and second magnetic resistance elements as a detection signal.

### CROSS REFERENCE TO RELATED APPLICATION

The present disclosure is based on Japanese Patent Application No.

2011-227854 filed on Oct. 17, 2011, the disclosures of which are incorporated herein by reference.

### TECHNICAL FIELD

The present disclosure relates to a magnetic sensor.

### BACKGROUND ART

Conventionally, a magnetic sensor formed by using a plurality of magnetic resistance elements has been proposed. The magnetic resistance element includes a pinned layer whose magnetization direction is fixed in a predetermined direction and a free layer whose magnetization direction changes in accordance with an external magnetic field. A resistance value of the magnetic resistance element changes as a sine wave or a cosine wave in accordance with an angle between the magnetization direction of the pinned layer and the magnetization direction of the free layer. Thus, a signal including a sine value or a signal including a cosine value is output from the magnetic sensor as a sensor signal.

However, if the signal including the sine value or the signal including the cosine value is output as the senor signal without any change, the sensor signal does not change linearly (proportionally) with respect to the angle between the magnetization direction of the pinned layer and the magnetization direction of the free layer and a detection accuracy changes with the angle between the magnetization direction of the pinned layer and the magnetization direction of the free layer.

Thus, for example, Patent Document 1 discloses a rotation sensor that includes a first magnetic resistance element whose resistance value changes as a sine wave, a second magnetic resistance element whose resistance value changes as a cosine wave, and arctan operation means performing an arctan operation to signals output from the first and second magnetic resistance elements.

Because the rotation sensor performs the arctan operation to the signals obtained from the first and second magnetic resistance elements and outputs an operation result as a sensor signal, the sensor signal changes linearly with respect to the angle between the magnetization direction of the pinned layer and the magnetization direction of the free layer.

However, in the above-described rotation sensor, although the sensor signal changes linearly with respect to the angle between the magnetization direction of the pinned layer and the magnetization direction of the free layer, a complicated device, circuit, program or the like for performing the arctan operation is necessary. Furthermore, by performing the arctan operation, a response speed decreases.

### PRIOR ART DOCUMENTS

### Patent Document

[Patent Document 1] JP-A-2009-258122

### SUMMARY OF INVENTION

It is an object of the present disclosure to provide a magnetic sensor that can restrict a difference in detection accuracy with respect to an angle between a magnetization direction of a pinned layer and a magnetization direction of a free layer with a simple configuration and can improve a response speed.

A magnetic sensor according to an aspect of the present disclosure includes a detection portion that includes a first magnetic resistance element and a second magnetic resistance element. Each of the first magnetic resistance element and the second magnetic resistance element includes a pinned layer whose magnetization direction is fixed in a predetermined direction and a free layer whose magnetization direction changes in accordance with an external magnetic field. A resistance value of each of the first magnetic resistance element and the second magnetic resistance element changes in accordance with an angle between the magnetization direction of the pinned layer and the magnetization direction of the free layer. The first magnetic resistance element and the second magnetic resistance element are connected in series in a state where the magnetization directions of the pinned layers are perpendicular to each other. The detection portion outputs a middle point voltage of the first magnetic resistance element and the second magnetic resistance element as a detection signal.

The magnetic sensor does not need a complicated device, circuit, program or the like for performing an arctan operation as a conventional magnetic sensor and can output a signal that changes almost linearly with respect to an angle (a magnetic field incident angle) between the magnetization direction of the pinned layer and the magnetization direction of the free layer within a predetermined angle range with a simple configuration. Furthermore, because the magnetic sensor does not need to perform an arctan operation, the magnetic sensor can improve a response speed.

### BRIEF DESCRIPTION OF DRAWINGS

The above and other objects, features and advantages of the present disclosure will become more apparent from the following detailed description made with reference to the accompanying drawings. In the drawings:

FIG. 1 is a circuit diagram illustrating a magnetic sensor according to a first embodiment of the present disclosure;

FIG. 2 is a cross-sectional view illustrating a first magnetic resistance element;

FIG. 3 is a diagram illustrating a simulation result of a relationship between a voltage of a sensor signal and a magnetic field incident angle;

FIG. 4(a) is a diagram illustrating an arrangement relationship between a detection portion and a throttle valve in a state where the throttle valve is completely closed, FIG. 4(b) is a diagram illustrating an arrangement relationship between the detection portion and the throttle valve in a state where the throttle valve is completely opened;

FIG. 5 is a diagram illustrating a simulation result of a relationship between a voltage of a sensor signal and a magnetic field incident angle at various resistance change rates α;

FIG. 6 is a diagram illustrating a relationship between a magnetic field incident angle and an error at various resistance change rates α;

FIG. 7 is a circuit diagram illustrating a magnetic sensor according to a second embodiment of the present disclosure;

FIG. 8 is a diagram illustrating a simulation result of a relationship between a middle point voltage of first and second magnetic resistance elements illustrated in FIG. 7 and a magnetic field incident angle and a relationship between a voltage of a sensor signal and the magnetic field incident angle; and

FIG. 9 is a diagram illustrating a simulation result of a relationship between a middle point voltage of first and second magnetic resistance elements and a magnetic field incident angle and a relationship between a voltage of a sensor signal and the magnetic field incident angle according to another embodiment of the present disclosure.

### EMBODIMENTS FOR CARRYING OUT INVENTION

### First Embodiment

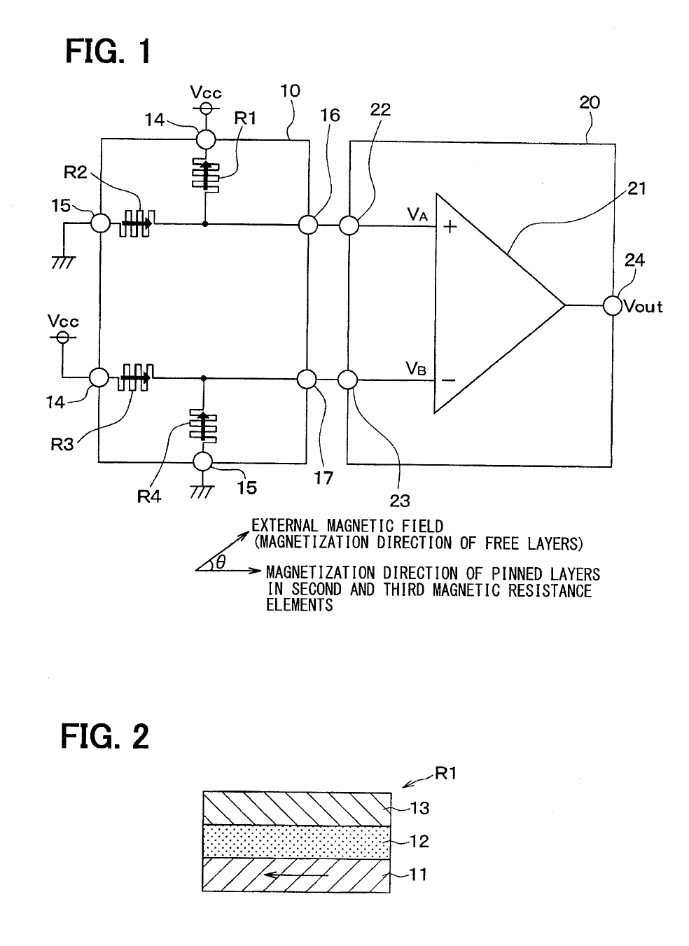

A first embodiment of the present disclosure will be described with reference to the drawings. FIG. 1 is a circuit diagram illustrating a magnetic sensor according to a first embodiment of the present disclosure. The magnetic sensor according to the present embodiment is suitably used for detecting a rotation angle of a rotation body that rotates within a predetermined angle range. For example, the magnetic sensor according to the present embodiment is suitably used for detecting a rotation angle of a throttle valve that controls the amount of intake air suctioned in a combustion chamber of an engine.

As illustrated in FIG. 1, the magnetic sensor includes a detection portion 10 and a signal processor 20. The detection portion 10 is, for example, a sensor chip in which first through fourth magnetic resistance elements R1-R4 are formed on a semiconductor substrate made of, for example, silicon. FIG. 2 is a cross-sectional view illustrating the first magnetic resistance element. As illustrated in FIG. 2, the first magnetic resistance element R1 is a general tunnel magnetic resistance element (TMR element) in which a pinned layer 11 whose magnetization direction is fixed in a predetermined direction, a tunnel layer 12 made of insulation body, and a free layer 13 whose magnetization direction changes in accordance with an external magnetic field are stacked in this order and a lower electrode and an upper electrode, which are not illustrated, are provided. The arrow in FIG. 2 indicates the magnetization direction of the pinned layer 11.

Although they are not illustrated, basic structures of the second through fourth resistance elements R2-R4 are similar to the structure of the first magnetic resistance element R1. Arrows illustrated in the respective magnetic resistance elements R1-R4 in FIG. 1 indicate magnetization directions of the pinned layers 11. As illustrated in FIG. 1, the first through fourth magnetic resistance elements R1-R4 form a full bridge circuit.

Specifically, the first and second magnetic resistance elements R1, R2 are electrically connected in series to form a half bridge circuit in a state where the magnetization directions of the pinned layers 11 are perpendicular to each other. In addition, the third and fourth magnetic resistance elements R3, R4 are electrically connected in series to form a half bridge circuit in a state where the magnetization directions of the pinned layers 11 are perpendicular to each other, the magnetization direction of the pinned layer 11 in the third magnetic resistance element R3 is parallel to the magnetization direction of the pinned layer 11 in the second magnetic resistance element R2, and the magnetization direction of the pinned layer 11 in the fourth magnetic resistance element R4 is parallel to the magnetization direction of the pinned layer 11 in the first magnetic resistance element R1.

Although they are illustrated as being separated in FIG. 1, the first and third magnetic resistance elements R1, R3 are connected and the second and fourth magnetic resistance elements R2, R4 are connected, that is, both of the half bridge circuits are connected in parallel to form a full bridge circuit.

The full bridge circuit is provided with a power supply terminal 14 and a ground terminal 15. The power supply terminal 14 is disposed at a middle point of the first and third magnetic resistance elements R1, R3 and applies a power supply voltage. The ground terminal 15 is disposed at a middle point of the second and fourth magnetic resistance elements R2, R4 to electrically connect with a ground G1. Between the first and third magnetic resistance elements R1, R2, an output terminal 16 for pulling out a middle point voltage V_{A} is disposed. Between the third and fourth magnetic resistance elements R3, R4, an output terminal 17 for pulling out a middle point voltage V_{B} is disposed. The middle point voltage V_{A} may also be referred to as a first detection signal, and the middle point voltage V_{B} may also be referred to as a second detection signal.

Because, in the detection portion 10, the magnetization directions of the pinned layers 11 in the first through fourth magnetic resistance elements R1-R4 are set as described above, when an external magnetic field that makes an angle θ with the magnetization direction of the pinned layers 11 in the second and third magnetic resistance elements R2, R3 as illustrated in FIG. 1 (hereafter, referred to as a magnetic field incident angle) is applied, that is, when the angle between the magnetization direction of the pinned layers 11 and the magnetization direction of the free layers 13 becomes θ, resistance values of the first and fourth magnetic resistance elements R1, R4 change into R₀+α sin θ, and resistance values of the second and third magnetic resistance elements R2, R3 change into R₀+α cos θ.

Note that R₀ is a resistance value of the magnetic resistance element when non magnetic field is applied (hereafter, referred to as a non-magnetic field resistance value), and α is a resistance change rate (sensitivity) depending on, for example, material forming the magnetic resistance element. Thus, the following signals are output from the output terminals 16, 17.

$$\begin{matrix}{V}_{A} = \frac{α cos θ + Ro}{α sin θ + α cos θ + 2 Ro} \cdot Vcc & [ Math . 1 ] \\ {V}_{B} = \frac{α sin θ + Ro}{α sin θ + α cos θ + 2 Ro} \cdot Vcc & [ Math . 2 ]\end{matrix}$$

The signal processor 20 includes a differential amplifier 21 that is formed of, for example, an operational amplifier. A non-inverting input terminal is connected to the output terminal 16 through an input terminal 22 and an inverting input terminal is connected to the output terminal 17 through an input terminal 23. Then, the signal processor 20 differentially amplifies the mathematical expression 1 and the mathematical expression 2 and outputs a sensor signal Vout from an output terminal 24. Here, there are following expressions in composition formulas of a trigonometric function.

$$\begin{matrix}a sin θ + b cos θ = \sqrt{{a}^{2} + {b}^{2}} \cdot sin ( θ + β ) & [ Math . 3 ] \\ β = {tan}^{- 1} ( \frac{b}{a} ) & [ Math . 4 ]\end{matrix}$$

Thus, the mathematical expression 2 is subtracted from the mathematical expression 1 and deformation is performed using the mathematical expression 3 and the mathematical expression 4 to obtain the following expression.

$$\begin{matrix}Vout = \frac{α \cdot \sqrt{2} \cdot sin ( η )}{α \cdot \sqrt{2} \cdot sin ( η + 90 ° ) + 2 Ro} \cdot Vcc \\ = \frac{α \cdot \sqrt{2} \cdot sin ( η )}{α \cdot \sqrt{2} \cdot cos ( η ) + 2 Ro} \cdot Vcc\end{matrix} \qquad [ Math . 6 ]$$

Here, the mathematical expression 5 is deformed by setting η=θ−45° to obtain the following expression.

$$\begin{matrix}{V}_{A} - {V}_{B} = \frac{- α sin θ + α cos θ}{α sin θ + α cos θ + 2 Ro} \cdot Vcc \\ = \frac{α \cdot \sqrt{2} \cdot sin ( θ - 45 ° )}{α \cdot \sqrt{2} \cdot sin ( θ + 45 ° ) + 2 Ro} \cdot Vcc\end{matrix} \qquad [ Math . 5 ]$$

Namely, the sensor signal Vout output from the signal processor 20 becomes the mathematical expression 6. Note that although an amplification factor of the differential amplifier 21 is set to 1 here, the amplification factor may be changed optionally. In the present embodiment, the differential amplification may also be referred to as a subtraction operation.

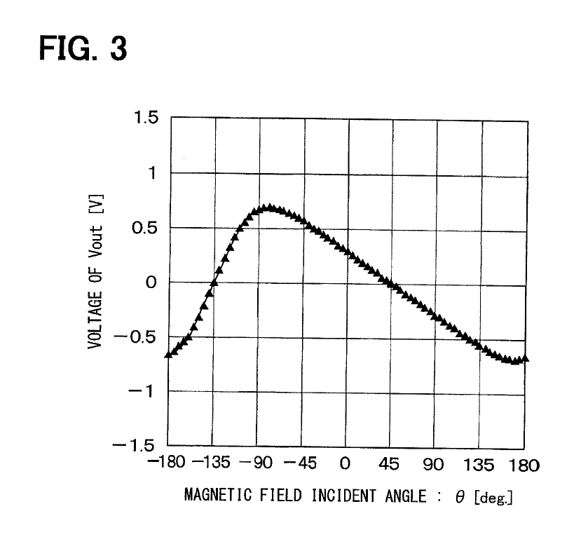

FIG. 3 is a diagram illustrating a simulation result of a relationship between the voltage of the sensor signal Vout and the magnetic field incident angle θ. The magnetic field incident angle θ in FIG. 3 is set such that when a direction parallel to the magnetization directions of the second and third magnetic resistance elements R2, R3 is set to 0°, a case where the external magnetic field is applied counterclockwise as illustrated in FIG. 1 is set to +θ and a case where the external magnetic field is applied clockwise is set to −θ. In addition, in FIG. 3, the resistance change rate α when the non-magnetic field resistance value R₀ is 1 is set to 80% of the non-magnetic field resistance value, and the power supply voltage Vcc is set to 1.

As illustrated in FIG. 3, the voltage of the sensor signal Vout changes almost linearly with respect to the magnetic field incident angle θ within the predetermined angle range of the magnetic field incident angle θ. Specifically, within a range from about −75°, which is the maximum point of the sensor signal Vout, to about 170°, which is the minimum point, the sensor signal Vout changes almost linearly with respect to the magnetic field incident angle θ. Note that the maximum point and the minimum point are points at which an inclination of the sensor signal Vout becomes 0.

Thus, the magnetic sensor according to the present embodiment is suitably used for detecting a rotation angle rotating within a range from about −75° to about 170°. For example, the magnetic sensor according to the present embodiment is suitably used for detecting a rotation angle of a throttle valve that controls the amount of intake air suctioned into a combustion chamber of an engine.

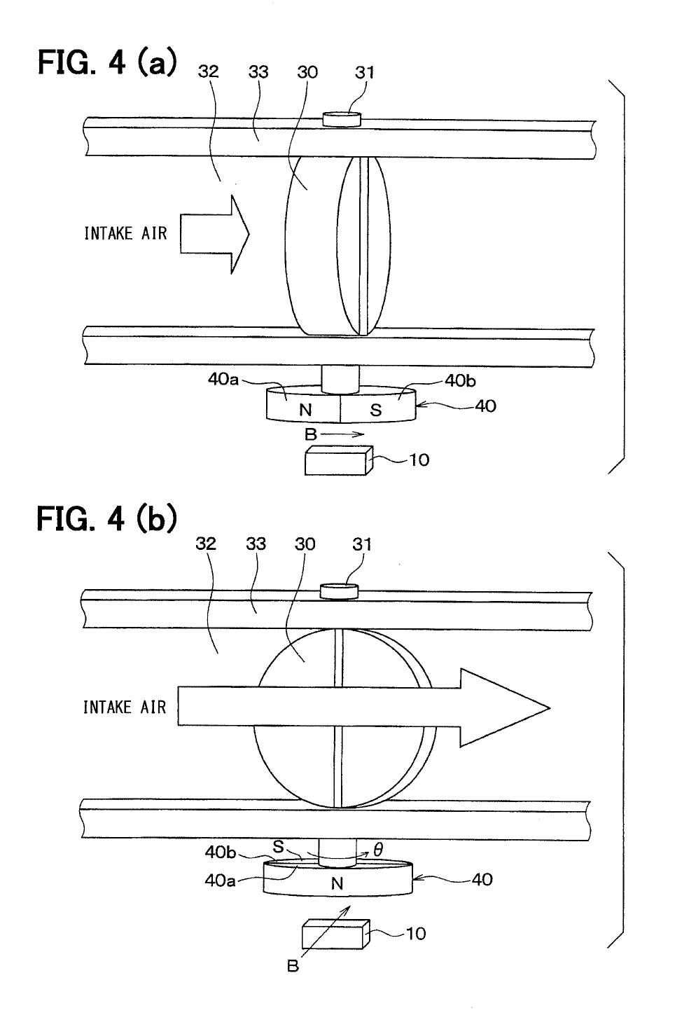

FIG. 4(a) is a diagram illustrating an arrangement relationship between the detection portion and a throttle valve in a state where the throttle valve is completely closed, and FIG. 4(b) is a diagram illustrating an arrangement relationship between the detection portion and the throttle valve in a state where the throttle valve is completely opened.

As illustrated in FIG. 4(a) and FIG. 4(b), a throttle valve 30 that controls the amount of intake air suctioned into a combustion chamber of an engine is integrated with a shaft 30 that rotates with the throttle valve 30. The shaft 31 is held by a throttle body 33 that forms a suction passage 32. Accordingly, the throttle valve 30 is disposed in the suction passage 32. Here, a cross section of the suction passage 32 to a flow direction of the intake air is circular shape. The throttle valve 30 has a circular plate shape having almost the same diameter as the suction passage 32 so that throttle valve 30 can block the intake air when the throttle valve 30 is completely closed. The shaft 31 is disposed to the throttle body 33 such that one end portion protrudes outside the suction passage 32, and the protruding end portion is attached with a permanent magnet 40. The permanent magnet 40 may be referred to as a rotation body.

The permanent magnet 40 has a circular plate shape and is bisected in a radial direction. One of the bisected portions is an N pole permanent magnet 40a and the other of the bisected portions is an S pole permanent magnet 40b. As illustrated in FIG. 4(b), the permanent magnet 40 rotates with the throttle valve 30 through the shaft 31.

The detection portion 10 is held by a supporting member, which is not illustrated, in an external magnetic field generated by the permanent magnet 40. Specifically, the detection portion 10 is disposed such that the magnetization direction of the pinned layers 11 in the second and third magnetic resistance elements R2, R3 are parallel to a direction of the external magnetic field B generated by the permanent magnet 40 when the throttle valve 30 is completely closed.

As illustrated in FIG. 4(a) and FIG. 4(b), the throttle valve 30 generally rotates within a range from a state of 0° at which the throttle valve 30 is completely closed to a state of 90° at which the throttle valve 30 is completely opened and rotates within the angle range between the maximum point and the minimum point of the sensor signal Vout of the magnetic sensor.

Thus, when the magnetic sensor according to the present embodiment is applied to detect a rotation angle of a rotating body such as the throttle valve 30, a complicated device, circuit, program or the like to perform an arctan operation is not necessary and a signal linear to the rotation angle can be obtained with a simple configuration.

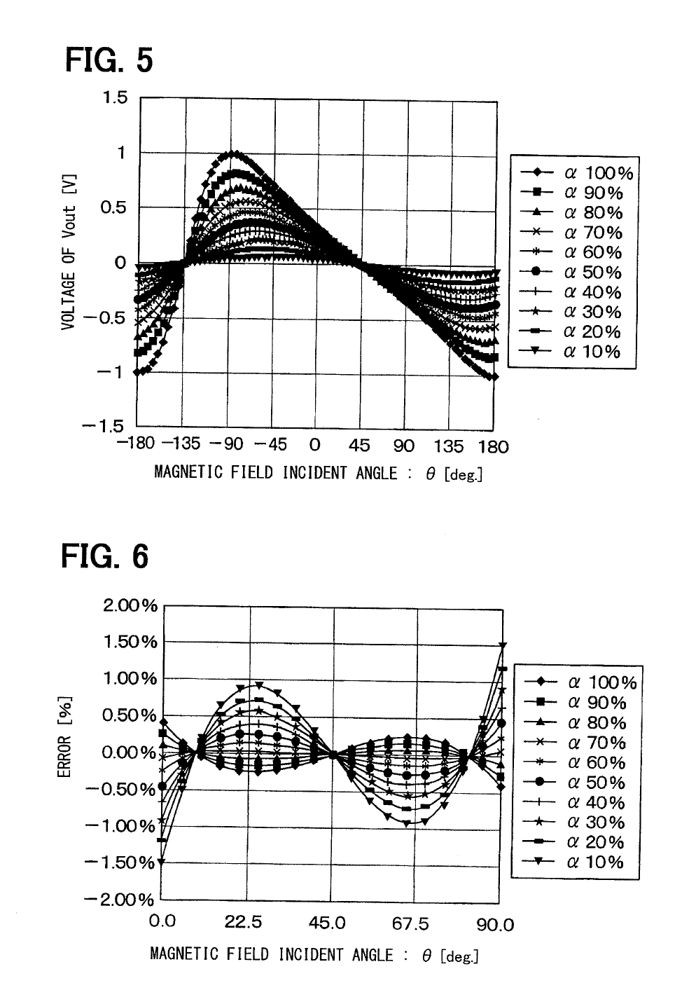

In FIG. 3, the example in which the resistance change rate α of the first through fourth magnetic resistance elements R1-R4 is 80% has been described. However, the resistance change rate α can be optionally changed. FIG. 5 is a diagram illustrating a simulation result of relationships between the voltage of the sensor signal Vout and the magnetic field incident angle θ at various resistance change rates α when the non-magnetic field resistance value R₀ is 1. In FIG. 5, the power supply voltage Vcc is set to 1.

As illustrated in FIG. 5, although there is a slight difference by the resistance change rate α of the first through fourth magnetic resistance elements R1-R4, by forming the magnetic sensor as described above, the sensor signal Vout that changes almost linearly with respect to the magnetic field incident angle θ within the predetermined angle range can be obtained. For example, in a case where the magnetic resistance rate α is 60%, the sensor signal Vout changes almost linearly with respect to the magnetic field incident angle θ within a range from −70°, which is the maximum point of the sensor signal Vout, to about 165°, which is the minimum point. In a case where the resistance change rate is 40%, the sensor signal Vout changes almost linearly with respect to the magnetic field incident angle θ within a rage from about −65°, which is the maximum point of the sensor signal Vout, to about 160°, which is the minimum point. In other words, regardless of the resistance change rate α the sensor signal Vout that changes almost linearly to the magnetic field incident angle θ within the predetermined angle range can be obtained.

FIG. 6 is a diagram illustrating a relationship between the magnetic field incident angle θ and an error at various resistance change rates α. The error is an error with respect to a straight line obtained by the least-squares method using points plotted in FIG. 5. As illustrated in FIG. 6, it is confirmed that, although the error increases when the magnetic field incident angle θ is 22.5°, 67.5°, and 90° at each of the resistance change rates α, the error decreases with increase in the resistance change rate α. Thus, it is preferable that the first through fourth magnetic resistance elements R1-R4 are configured so that the resistance change rate α is high.

As described above, in the magnetic sensor according to the present embodiment, the first and second magnetic resistance elements R1, R2 are electrically connected in series to form the half bridge circuit in the state where the magnetization directions of the pinned layers 11 are perpendicular to each other. In addition, the third and fourth magnetic resistance elements R3, R4 are electrically connected in series to form the half bridge circuit in the state where the magnetization directions of he pinned layers 11 are perpendicular to each other, the magnetization direction of the pinned layer 11 in the third magnetic resistance element R3 is parallel to the magnetization direction of the pinned layer 11 in the second magnetic resistance element R2, and the magnetization direction of the pinned layer 11 in the fourth magnetic resistance element R4 is parallel to the magnetization direction of the pinned layer 11 in the first magnetic resistance element R1.

The differential amplifier 21 in the signal processor 20 differentially amplifies the middle point voltage V_{A} of the first and second resistance elements R1, R2 and the middle point voltage V_{B} of the third and fourth magnetic resistance elements R3, R4 and outputs the differentially-amplified result as the sensor signal Vout.

Thus, as illustrated in FIG. 3 and FIG. 5, the sensor signal Vout that changes almost linearly with respect to the magnetic field incident angle a within the predetermined angle range can be output.

In addition, the magnetic sensor can be obtained by changing the arrangement method of the first through fourth magnetic resistance elements R1-R4 and by providing the differential amplifier 21 having a simple configuration, such as an operational amplifier, with respect to the conventional magnetic sensor, and a complicated device, circuit, program or the like is not necessary. Thus, the configuration can be simplified. Furthermore, because the magnetic sensor does not perform an operation such as an arctan operation, the magnetic sensor can improve a response speed. In addition, by forming the detection portion 10 with the full bridge circuit, the detection sensitivity can be increased.

### Second Embodiment

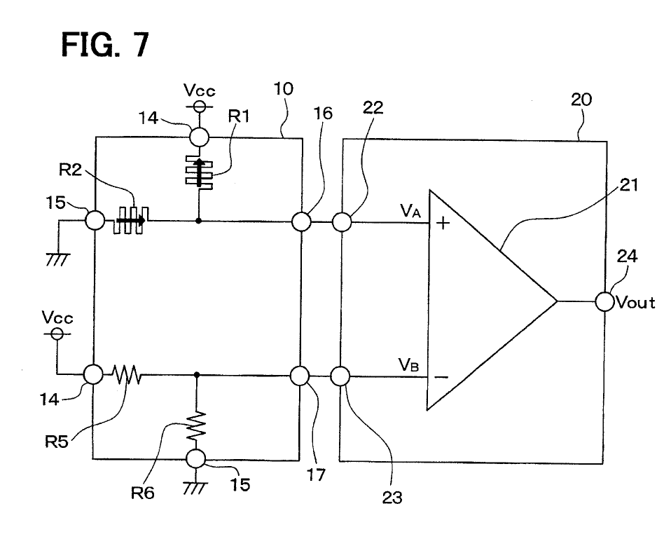

A second embodiment of the present disclosure will be described. In the present embodiment, the detection portion 10 is formed of the first and second magnetic resistance elements R1, R2 and first and second resistors with respect to the first embodiment. Because the other portions are same as the first embodiment, a description about the other portions is omitted. FIG. 7 is a circuit diagram illustrating a magnetic sensor according to a second embodiment of the present disclosure.

As illustrated in FIG. 7, the detection portion 10 according to the present embodiment includes first and second resistors R5, R6 instead of the third and fourth magnetic resistance elements R3, R4 in the first embodiment, and the first and second magnetic resistance elements R1, R2 and the first and second resistors R5, R6 form a full bridge circuit.

A middle point voltage Vb of the first and second resistors R5, R6 is input to the inverting input terminal of the differential amplifier 21. In the present embodiment, resistance values of the first and second resistors R5, R6 are set to be equal to each other, and Vcc/2 is input to the inverting input terminal of the differential amplifier 21.

The voltage input to the inverting input terminal of the differential amplifier 21 is not limited to Vcc/2 and can be changed optionally. For example, a voltage having the same temperature characteristic as the first and second magnetic resistance elements R1, R2 may be input. Specifically, the first and second resistors R5, R6 may be set to resistors having the same temperature characteristic as the first and second magnetic resistance elements R1, R2. Accordingly, the temperature characteristic of the first and second magnetic resistance elements R1, R2 can be compensated, and the detection accuracy can be improved.

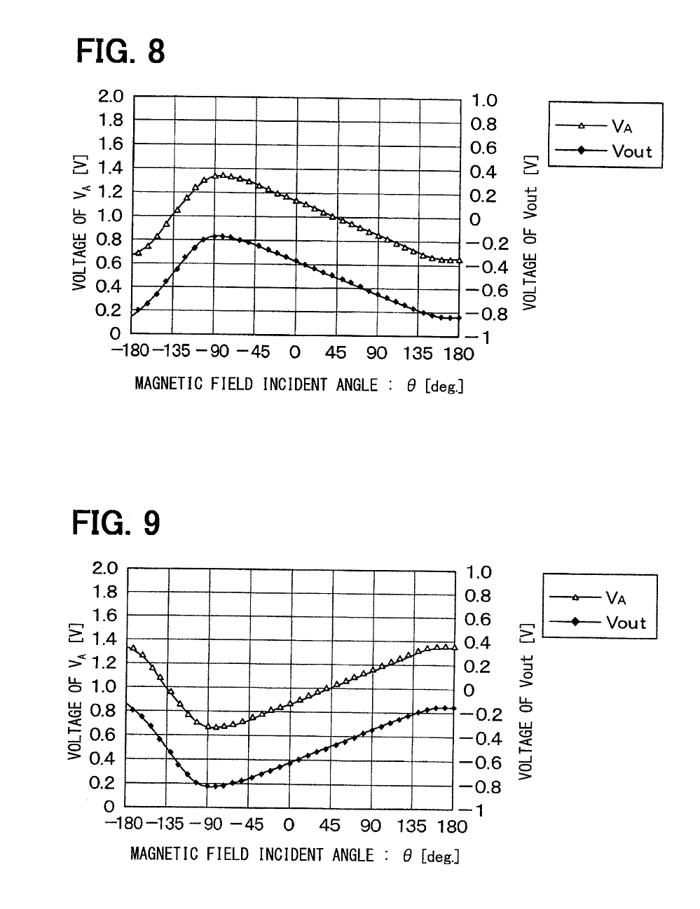

Also this magnetic sensor can output the sensor signal Vout that changes almost linearly with respect to the magnetic filed incident angle a within the predetermined angle range, and the same effects as the first embodiment can be obtained. FIG. 8 is a diagram illustrating a simulation result of a relationship between the middle point voltage V_{A} of first and second magnetic resistance elements R1, R2 and the magnetic field incident angle θ, and a relationship between the voltage of the sensor signal Vout and the magnetic field incident angle θ. None that, in FIG. 8, the resistance change rate α when the non-magnetic field resistance value R₀ is 1 is set to 80% of the non-magnetic field resistance value, and the power supply voltage Vcc is set to 1.

As illustrated in FIG. 8, in the magnetic sensor according to the present embodiment, within a range from about −80°, which is the maximum point of the sensor signal Vout, to about 170°, which is the minimum point, the sensor signal Vout changes almost linearly with respect to the magnetic field incident angle θ.

In FIG. 8, also the middle point voltage V_{A} of the first and second magnetic resistance elements R1, R2 is illustrated. Also the middle point voltage V_{A} changes almost linearly with respect to the magnetic field incident angle θ within a range from about −80°, which is the maximum point, to about 170°, which is the minimum point. Thus, the magnetic sensor may be formed only with the detection portion 10, and the middle point voltage V_{A} of the first and second magnetic resistance elements R1, R2 may be output without any change. Because this magnetic sensor does not need the signal processor 20, the configuration of the magnetic sensor can be further simplified.

### Other Embodiments

In each of the above-described embodiments, the example in which the voltage depending on the magnetic field incident angle θ is output from the magnetic sensor has been described. However, a magnetic sensor may be configured as described below. Namely, the signal processor 20 may include a conversion portion, and the conversion portion may convert the voltage output from the differential amplifier 21 and may output the converted result. For example, when the conversion portion includes, for example, a semiconductor memory storing a map in which the voltage and θ are matched, the conversion portion can convert the voltage output from the differential amplifier 21 and can output the converted result.

In each of the above-described embodiments, the example in which the signal output from the detection portion 10 is differentially amplified by the differential amplifier 21 such as the operational amplifier, that is, the signal is differentially amplified in a state where the signal remains an analog signal. However, after the signal output from the detection portion 10 is converted into a digital signal, the digital signal may be differentially amplified (subtracted). In this way, even when the differential amplification is performed after the signal output from the detection portion 10 is converted into the digital signal, compared with a case in which an arctan operation is performed as the conventional art, only simple differential amplification (subtraction) needs to be performed, and the configuration can be simplified.

Furthermore, in the first embodiment, gigantic magnetic resistance elements (GMR elements) in which conductive bodes are disposed between the pinned layers 11 and the free layers 13 may be used as the first through fourth magnetic resistance elements R1-R4, and in the second embodiment, gigantic magnetic resistance elements (GMR elements) in which conductive bodies are disposed between the pinned layers 11 and the free layers 13 may be used as the first and the second magnetic resistance elements R1, R2.

In addition, in the second embodiment, the example in which the resistance value of the first magnetic resistance element R1 is changed into R₀+α sin θ and the resistance value of the second magnetic resistance element R2 is changed into R₀+α cos θ has been described. However, the resistance value of the first magnetic resistance element R1 may also be changed into R₀+α cos θ and the resistance value of the second magnetic resistance element R2 may also be changed into R₀+α sin θ. FIG. 9 is a simulation result indicating a relationship between the voltage of the sensor signal Vout and the magnetic field incident angle θ according to another embodiment.

As illustrated in FIG. 9, also in this magnetic sensor, within a range from about −80°, which is the minimum point of the sensor signal Vout, to about 170°, which is the maximum point, the sensor signal Vout changes almost linearly with respect to the magnetic field incident angle θ. Similarly to FIG. 8, in FIG. 9, also the middle point voltage V_{A} of the first and second magnetic resistance elements R1, R2 is illustrated. Also the middle point voltage V_{A} changes almost linearly with respect to the magnetic field incident angle θ within a range from about −80°, which is the maximum point, to about 170°, which is the minimum point. Thus, the magnetic sensor may be formed only with the detection portion 10, and the middle point voltage V_{A} of the first and second magnetic resistance elements R1, R2 may be output without any change.

1. A magnetic sensor comprising
a detection portion including a first magnetic resistance element and a second magnetic resistance element,
wherein each of the first magnetic resistance element and the second magnetic resistance element includes a pinned layer whose magnetization direction is fixed in a predetermined direction and a free layer whose magnetization direction changes in accordance with an external magnetic field, wherein a resistance value of each of the first magnetic resistance element and the second magnetic resistance element changes in accordance with an angle between the magnetization direction of the pinned layer and the magnetization direction of the free layer,
wherein the first magnetic resistance element and the second magnetic resistance element are connected in series in a state where the magnetization directions of the pinned layers are perpendicular to each other, and
wherein the detection portion outputs a middle point voltage of the first magnetic resistance element and the second magnetic resistance element as a detection signal.

2. The magnetic sensor according to claim 1, further comprising
a signal processor performing a predetermined operation using the detection signal,
wherein the detection portion further includes a third magnetic resistance element and a fourth magnetic resistance element,
wherein the third magnetic resistance element includes a pinned layer whose magnetization direction is fixed in a direction parallel to the magnetization direction of the pinned layer in the second magnetic resistance element and a free layer whose magnetization direction changes in accordance with the external magnetic field, a resistance value of the third magnetic resistance element changes in accordance with an angle between the magnetization direction of the pinned layer and the magnetization direction of the free layer, and the third magnetic resistance element is connected to a power source with the first magnetic resistance element,
wherein the fourth magnetic resistance element includes a pinned layer whose magnetization direction is fixed in a direction parallel to the magnetization direction of the pinned layer in the first magnetic resistance element and a free layer whose magnetization direction changes in accordance with the external magnetic field, a resistance value of the fourth magnetic resistance element changes in accordance with an angle between the magnetization direction of the pinned layer and the magnetization direction of the free layer, the fourth magnetic resistance element is grounded with the first magnetic resistance element and is connected in series with the third magnetic resistance element,
wherein the first magnetic resistance element, the second magnetic resistance element, the third magnetic resistance element, and the fourth magnetic resistance element form a full bridge circuit,
wherein the detection portion outputs a middle point voltage of the third magnetic resistance element and the fourth magnetic resistance element as a second detection signal while outputting the middle point voltage of the first magnetic resistance element and the second magnetic resistance element as the first detection signal, and
wherein the signal processor carrying out an operation of subtracting the second detection signal from the first detection signal, and outputs an operation result as a sensor signal.

3. The magnetic sensor according to claim 1, further comprising
a signal processor differentially amplifying the detection signal with respect to a reference voltage,
wherein the signal processor outputs an amplified result as a sensor signal.

4. The magnetic sensor according to claim 3,
wherein the signal processor uses a voltage having a same temperature characteristic with the first magnetic resistance element and the second magnetic resistance element as the reference voltage.

5. The magnetic sensor according to claim 2,
wherein the detection portion is disposed in the external magnetic field generated by a rotation body rotating within an angle range between a maximum point and a minimum point of the sensor signal.

6. The magnetic sensor according to claim 1,
wherein the detection portion is disposed in the external magnetic field generated by a rotation body rotating within an angle range between a maximum point and a minimum point of the detection signal.
